(19) United States
(12) Patent Application Publication
(10) Pub. No.: US 2024/0074253 A1
(43) Pub. Date: Feb. 29, 2024

(54) DISPLAY DEVICE

(71) Applicant: LG Display Co., Ltd., Seoul (KR)

(72) Inventors: Sunyoung CHOI, Seoul (KR); Sangsoon NOH, Goyang-si (KR); Dongchae SHIN, Goyang-si (KR); Moonho PARK, Gimpo-si (KR); Mijin JEONG, Seoul (KR)

(73) Assignee: LG Display Co., Ltd., Seoul (KR)

(21) Appl. No.: 18/238,714

(22) Filed: Aug. 28, 2023

(30) Foreign Application Priority Data
Aug. 30, 2022 (KR) 10-2022-0109060

(51) Int. Cl. H10K 59/126

(52) U.S. Cl. CPC H10K 59/126

(57) ABSTRACT

A display device may include a display area; a non-display area including a driver circuit area; a first transistor disposed in the display area, the first transistor including a first semiconductor layer, a first gate electrode, a first source electrode, and a first drain electrode; a second transistor disposed in the driver circuit area, the second transistor including a second semiconductor layer, a second gate electrode, a second source electrode, and a second drain electrode; and a first insulating film disposed between the second gate electrode and the second source electrode and between the second gate electrode and the second drain electrode; an anode electrode electrically connected to the first drain electrode; and a light-blocking layer overlapping the first semiconductor layer and disposed on the first insulating film. The light-blocking layer, the second source electrode, and the second drain electrode may be disposed on the same layer.

### CROSS-REFERENCE TO RELATED APPLICATION

This application claims the benefit of and priority to Korean Patent Application No. 10-2022-0109060 filed on Aug. 30, 2022, the entirety of which is incorporated herein by reference for all purposes.

### BACKGROUND

### 1. Technical Field

The present disclosure relates to a display device and particularly to, for example, without limitation, a display device including a plurality of thin-film transistors, the components of which exhibit improved reliability.

### 2. Discussion of the Related Art

Recent display devices capable of displaying various information and interacting with users who view the information are required to have various sizes, various shapes, and various functions.

These display devices may include, for example, a liquid crystal display device (LCD), an electrophoretic display device (EPD), and an organic light-emitting diode display device (OLED).

An organic light-emitting diode display device is a self-luminous display device and does not require a separate light source, which is not the case for the LCD, and thus an organic light-emitting diode display device may be manufactured in a lightweight and thin form. Moreover, an organic light-emitting diode display device is not only advantageous in terms of power consumption due to low voltage operation but also superior in terms of color rendering, response speed, viewing angle, and contrast ratio (CR), and thus an organic light-emitting diode display device is being studied as a next-generation display.

An organic light-emitting diode display device can control current flowing through an organic light-emitting diode using a plurality of thin-film transistors (TFTs) to display an image.

Each of the plurality of thin-film transistors may be a thin-film transistor using a low-temperature polycrystalline silicon semiconductor or a thin-film transistor using an oxide semiconductor made of an oxide.

However, when the thin-film transistor employs an oxide semiconductor, a channel area of an oxide semiconductor may become conductive due to hydrogen and light generated internally or originated externally. Accordingly, characteristics of the components of such thin-film transistor may be degraded.

The description provided in the discussion of the related art section should not be assumed to be prior art merely because it is mentioned in or associated with that section. The discussion of the related art section may include information that describes one or more aspects of the subject technology, and the description in this section does not limit the invention.

### SUMMARY

The inventors of the present disclosure have recognized the problems and disadvantages of the related art, have performed extensive research and experiments, and have developed a new invention.

According to one or more aspects of the present disclosure, a purpose to be achieved by the present disclosure is to provide a display device including different types of semiconductors in which characteristics of the components of a transistor including an oxide semiconductor are stably secured.

Purposes according to the present disclosure are not limited to the above-mentioned purpose. Other purposes and advantages according to the present disclosure are set forth in the present disclosure and may also be understood based on the descriptions or the inventive concepts provided herein, and may be more clearly understood based on embodiments according to the present disclosure. Further, the purposes and advantages according to the present disclosure may be realized using means shown in the claims, drawings or combinations thereof.

A display device according to one or more example embodiments of the present disclosure may include: a substrate; a display area; a non-display area disposed around the display area; a driver circuit area and a dam area disposed in the non-display area; a first transistor disposed in the display area, wherein the first transistor includes a first semiconductor layer, a first gate electrode, a first source electrode, and a first drain electrode; a second transistor disposed in the driver circuit area, wherein the second transistor includes a second semiconductor layer, a second gate electrode, a second source electrode, and a second drain electrode; and a first insulating film disposed between the second gate electrode and the second source electrode and between the second gate electrode and the second drain electrode; an anode electrode electrically connected to the first drain electrode; and a light-blocking layer overlapping the first semiconductor layer, wherein the light-blocking layer is disposed on the first insulating film, and wherein the light-blocking layer, the second source electrode, and the second drain electrode are disposed on a same layer.

Details of one or more example embodiments are provided in this disclosure, including the claims and drawings.

In the display device using thin-film transistors including different types of semiconductors according to one or more example embodiments of the present disclosure, stability of the thin-film transistor including an oxide semiconductor may be secured, thereby improving display quality.

In addition to the above effects, specific effects of the present disclosure are described together while describing specific details for carrying out the present disclosure.

Effects of the present disclosure are not limited to the effects mentioned above, and other effects not mentioned will be clearly understood by those skilled in the art from the descriptions herein.

Other apparatuses, methods, features and advantages will be, or will become, apparent to one with skill in the art upon examination of the drawings and detailed description herein. It is intended that all such apparatuses, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are exemplary and explanatory, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles of the disclosure.

FIG. 1 is a block diagram of a display device according to an example embodiment of the present disclosure.

FIG. 2 is a block diagram of a sub-pixel of a display device according to an example embodiment of the present disclosure.

FIG. 3 is a cross-sectional view of a display device according to an example embodiment of the present disclosure.

FIG. 4A to FIG. 4H are cross-sectional views illustrating a method for manufacturing a transistor including an oxide semiconductor of a display device according to an example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION

Advantages and features of the present disclosure, and methods of achieving the advantages and features will become apparent with reference to embodiments described herein together with the accompanying drawings. However, the present disclosure is not limited to the embodiments disclosed herein, but may be implemented in various different forms. Thus, these embodiments are examples and are provided so that this disclosure may be thorough and complete to assist those skilled in the art to understand the inventive concepts without limiting the protected scope of the present disclosure.

For simplicity and clarity of illustration, elements in the drawings are not necessarily drawn to scale. Unless stated otherwise, the same reference numbers in different drawings may represent the same or similar elements, and as such may perform similar functionality. In one or more aspects, identical elements (or elements with identical names) in different drawings may have the same or substantially the same functions and properties unless stated otherwise. Further, descriptions and details of well-known steps and elements are omitted for simplicity of the description. Further, repetitive descriptions may be omitted for brevity. Moreover, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure as defined by the appended claims.

The sequence of steps, functions and/or operations is not limited to that set forth herein and may be changed to occur in an order that is different from an order described herein, with the exception of steps, functions and/or operations necessarily occurring in a particular order. In one or more examples, two operations in succession may be performed substantially concurrently, or the two operations may be performed in a reverse order or different order depending on a function or operation involved.

Shapes, dimensions (e.g., sizes, lengths, widths, heights, thicknesses, locations, radii, diameters, and areas), ratios, angles, numbers, the number of elements, and the like disclosed herein, including those illustrated in the drawings, are merely examples, and thus, the present disclosure is not limited to the illustrated details.

The terminology used herein is directed to the purpose of describing particular example embodiments only and is not intended to be limiting of the present disclosure. When the term “comprise,” “have,” “include,” “contain,” “constitute,” “made of,” “formed of,” “composed of,” or the like is used with respect to one or more elements, one or more other elements may be added unless a term such as “only” or the like is used. The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects” and the like should not be construed to be preferred or advantageous over other implementations. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, where the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “on a top of,” “upon,” “on top of,” “over,” “under,” “above,” “below,” “beneath,” “near,” “close to,” “adjacent to,” “beside,” or “next to” another structure, this description should be construed as including a case in which the structures contact each other directly as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus another event may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, or the like), these elements should not be limited by these terms. These terms are used only to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is “connected,” “coupled,” “attached,” or “adhered” to another element, the element can not only be directly connected, coupled, attached, or adhered to another element, but also be indirectly connected, coupled, attached, or adhered to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The terms such as a “line” or “direction” should not be interpreted only based on a geometrical relationship in which the respective lines or directions are parallel or perpendicular to each other, and may be meant as lines or directions having wider directivities within the range within which the components of the present disclosure can operate functionally.

The term “at least one” should be understood as including any and all combinations of one or more of the associated listed items. For example, the meaning of “at least one of a first item, a second item, or a third item” denotes the combination of items proposed from two or more of the first item, the second item, and the third item as well as only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together. The embodiments of the present disclosure may be implemented or carried out independently of each other or may be implemented or carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In description of flow of a signal, for example, when a signal is provided from a node A to a node B, this may include a case where the signal is transferred from the node A to the node B via one or more nodes unless a phrase such as “immediately transferred,” “directly transferred” or the like is used.

In one or more examples, the term “display device” may include a display device including a liquid crystal module (LCM), an organic light-emitting diode (OLED) module, or a quantum dot (QD) module including a display panel and a driver for driving the display panel. In one or more other examples, the display device may include a set electronic device, a set device or a set apparatus including a complete product or a final product including the LCM, the OLED module, or the QD module, such as a laptop computer, a television, a computer monitor, an automotive device, a mobile electronic device such as a smartphone, or an electronic pad.

Therefore, the display device in accordance with one or more examples of the present disclosure may include, in a narrow aspect, a display device itself including, for example, the LCM, the OLED module, the QD module, or another module, or may include, in a broad aspect, the set device as an application product or an end-user device including a complete product or a final product including the LCM, the OLED module, or the QD module.

Moreover, in one or more examples, the LCM, the OLED module, or the QD module composed of the display panel and the driver may be referred to as a display device. In one or more other examples, an electronic device that is a complete product including the LCM, the OLED module or the QD module may be referred to as a set device. For instance, the display device, in one or more examples, may include a display panel such as a liquid crystal panel, an organic light-emitting display panel, or a quantum dot display panel, and a source printed circuit board (PCB) as a controller for driving the display panel. In one or more other examples, the set device may include a display panel such as a liquid crystal panel, an organic light-emitting display panel, or a quantum dot display panel, a source PCB as a controller for driving the display panel, and a set PCB as a set controller that is electrically connected to the source PCB and controls the set device.

A display panel may be of any type of display panel such as a liquid crystal display panel, an organic light emitting diode (OLED) display panel, a quantum dot (QD) display panel, an electroluminescent display panel, or the like. Embodiments are not limited thereto. For example, the display panel may be embodied as a display panel which may be vibrated by a vibrating device according to one or more example embodiments of the present disclosure to generate a sound. A display panel applied to a display device according to one or more example embodiments of the present disclosure is not limited to a shape or a size of the display panel.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

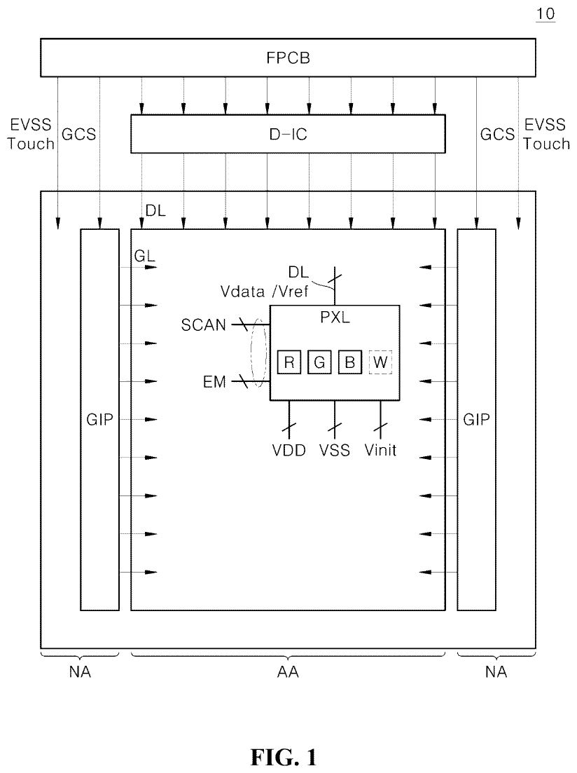

FIG. 1 is a block diagram illustrating a display device according to an example embodiment of the present disclosure.

A display device 10 may include a plurality of areas. For example, the display device 10 may include one or more display areas AA where an image is displayed, and a pixel PXL may be formed in the display area AA. One or more non-display areas NA in which an image is not displayed may include a driver circuit area and a dam area, and may be disposed on one side of the display area AA. For example, the non-display area NA may be adjacent to one or more sides of the display area AA.

Referring to FIG. 1, the non-display area NA may surround the display area AA of a rectangular shape. However, it should be understood that a shape of the display area AA and a position of the non-display area NA adjacent to the display area AA are not specifically limited to those of the display device 10 as shown in FIG. 1. Each of the display area AA and the non-display area NA may have any shape. Examples of these shapes may include a pentagon, a hexagon, a circle, an oval, or one or more other shapes. An embodiment of the present disclosure is not limited thereto.

The pixel PXL in the display area AA includes sub-pixels. The sub-pixels may display colors such as red (R), green (G), blue (B), and white (W). Moreover, each pixel PXL or sub-pixel may be associated with a pixel circuit including one or more transistor, such as one or more thin-film transistors (TFTs) which are disposed on a substrate of the display device 10. Each pixel circuit may be electrically connected to a gate line GL and a data line DL to communicate with one or more driver circuits, for example, a gate driver GIP and a data driver D-IC disposed in the non-display area NA of the display device 10.

One or more driver circuits may be implemented as TFTs disposed in the non-display area NA as shown in FIG. 1. For example, the gate driver GIP may be implemented using a plurality of TFTs on the substrate of the display device 10. Non-limiting examples of circuits that may be implemented as the TFTs of the substrate include an inverter circuit, a multiplexer, and an electro-static discharge (ESD) circuit. An embodiment of the present disclosure is not limited thereto.

Some driver circuits may be provided as integrated circuit (IC) chips, and may be mounted in the non-display area NA of the display device 10 using a chip-on-glass (COG) or in other similar schemes. Moreover, some driver circuits may be mounted on another substrate, and may be coupled to a connection interface (e.g., pads/bumps, pins) disposed in the non-display area NA using a printed circuit board (PCB) such as a flexible printed circuit board (FPCB), a chip-on-film (COF), a tape-carrier-package (TCP) or other suitable schemes.

In one or more example embodiments of the present disclosure, at least two different types of TFTs are disposed on a TFT substrate for display. The types of TFTs employed in a portion of the pixel circuit and a portion of the driver circuit may vary according to requirements of a display device.

For example, the pixel circuit may be implemented using a TFT with an oxide active layer (e.g., an oxide TFT). The driver circuit may be implemented using a TFT with a low-temperature polycrystalline silicon (LTPS) active layer (e.g., an LTPS TFT) and a TFT with an oxide active layer. Unlike the LTPS TFTs, the oxide TFTs do not suffer from pixel-to-pixel threshold voltage (Vth) variation. A uniform threshold voltage (Vth) may also be obtained in an array of pixel circuits for display. The uniformity problem of the threshold voltages (Vth) of the TFTs implemented in the driver circuit may have less direct impact on the luminance uniformity of the pixels.

The driver circuits (for example, the gate driver GIP) may have the gate driver IC embedded inside the display panel to reduce the number of driver ICs to achieve cost reduction, and may provide a high-speed scan signal to the display area of the display panel.

Using the driver circuits on the substrate implemented using the LTPS TFTs, signals and data may be provided to pixels at a higher clock speed than that when all TFTs in the TFT panel are embodied as oxide TFTs. Therefore, the display device capable of high-speed operation may be realized. For example, the advantages of the oxide TFT and the LTPS TFT are combined with the design of the TFT panel such that the oxide TFT and the LTPS TFT may be selectively used according to the advantages thereof.

Referring to FIG. 1, a low-potential voltage EVSS, a touch signal ToE, and a gate control signal GCS output from the flexible printed circuit board (FPCB) are applied to the display panel, and a high-potential voltage is applied to the display panel via the data driver D-IC.

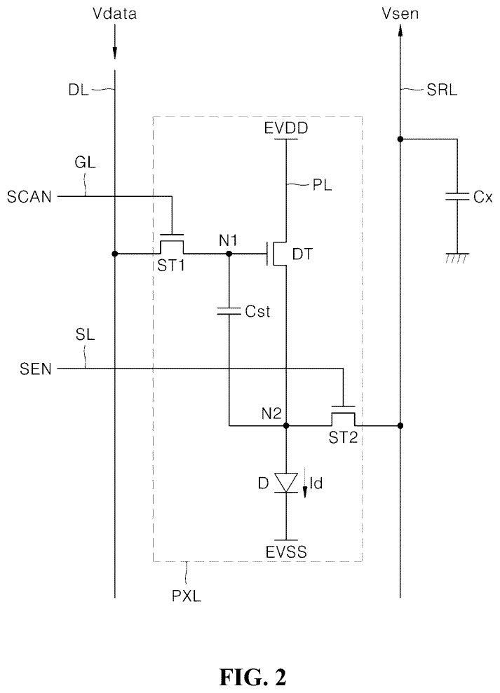

The gate driver GIP may be provided with a first driver circuit and a second driver circuit. The first driver circuit may provide a gate signal SCAN, which may be provided to a switching transistor ST1 (see FIG. 2) of the pixel PXL. The first driver circuit may transmit the gate signal SCAN to turn on/off the switching transistor ST1. The second driver circuit may provide a light-emission signal EM (or a sense signal SEN of FIG. 2) to another switching transistor ST2 (see FIG. 2) of the pixel PXL.

FIG. 2 illustrates a pixel circuit that may be used in one or more example embodiments of the present disclosure. FIG. 2 illustrates an example in which the display device has a structure including three thin-film transistors (3T) and one storage capacitor (1C), which may be referred to as a 3T1C structure. However, the display device of the present disclosure is not limited to this structure, and may have various structures such as 4T1C, 5T1C, 6T1C, 7T1C, 8T1C, 4T2C, 5T2C, 6T2C, 7T2C, and 8T2C, where the number before the letter T refers to the number of TFTs, and the number before the letter C refers to the number of storage capacitors.

Referring to FIG. 2, the display device 10 according to an example embodiment of the present disclosure may include the gate line GL, the data line DL, a power line PL, and a sensing line SL. Each sub-pixel SP may include a first switching thin-film transistor ST1, a second switching thin-film transistor ST2, a driving thin-film transistor DT, a light-emitting element D, and a storage capacitor Cst. However, embodiments of the present disclosure are not limited thereto.

The light-emitting element D includes an anode electrode connected to a second node N2, a cathode electrode connected to an input of the low-potential driving voltage EVSS, and a light-emitting element layer disposed between the anode electrode and the cathode electrode. The light-emitting element D may be an organic light-emitting element. However, embodiments of the present disclosure are not limited thereto.

The driving thin-film transistor DT may control current Id flowing through the light-emitting element D based on a voltage difference Vgs between a voltage of a gate and that of a source, where the gate and the source are the gate and the source, respectively, of the driving thin-film transistor DT. The driving thin-film transistor DT may include a gate electrode connected to a first node N1, a drain electrode connected to the power line PL so as to provide a high-potential driving voltage EVDD thereto, and a source electrode connected to the second node N2.

The storage capacitor Cst is disposed between and connected to the first node N1 and the second node N2. The storage capacitor Cst allows a predefined voltage to be maintained for one frame.

The first switching thin-film transistor ST1 may apply a data voltage Vdata charged in the data line DL to the first node N1 in response to a gate signal SCAN so as to turn on the driving thin-film transistor DT during an operation of the display panel. In this regard, the first switching thin-film transistor ST1 may include a gate electrode connected to the gate line GL for receiving the gate signal SCAN therefrom, a drain electrode connected to the data line DL for receiving the data voltage Vdata therefrom, and a source electrode connected to the first node N1.

The second switching thin-film transistor ST2 switches a current between the second node N2 and a sensing voltage read-out line SRL in response to a sensing signal SEN such that a source voltage of the second node N2 is stored in a sensing capacitor Cx of the sensing voltage read-out line SRL. The second switching thin-film transistor ST2 switches a current between the second node N2 and the sensing voltage read-out line SRL in response to the sensing signal SEN during an operation of the display panel such that the source voltage of the driving thin-film transistor DT is reset with an initialization voltage Vpre. A gate electrode of the second switching thin-film transistor ST2 is connected to the sensing line SL, a drain electrode thereof is connected to the second node N2, and a source electrode thereof is connected to the sensing voltage read-out line SRL.

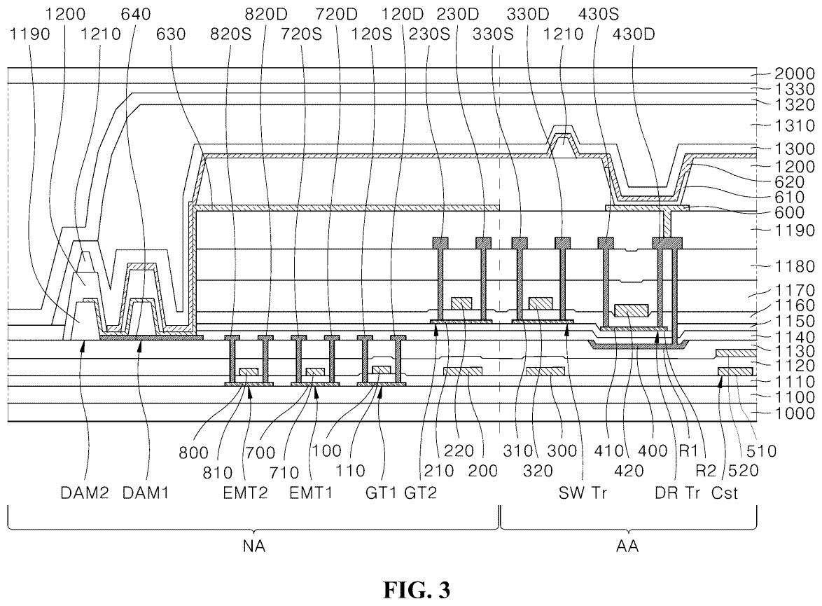

FIG. 3 is a cross-sectional view of a display device according to an example embodiment of the present disclosure.

Although not shown in the drawing, a substrate 1000 of the display device according to an example embodiment of the present disclosure may include a first substrate and a second substrate, and an intermediate layer between the first substrate and the second substrate.

The first substrate and the second substrate may be made of at least one of polyimide, polyethersulfone, polyethylene terephthalate, and polycarbonate. Embodiments of the present disclosure are not limited thereto. When the substrate is made of a plastic material, a manufacturing process of the display device may proceed in a manner where a support substrate made of glass is disposed under the substrate. Then, after the manufacturing process of the display device is completed, the support substrate may be released (or removed). Further, after the support substrate is released, a plate (or a back plate) to support the substrate may be disposed under the substrate. When the substrate is made of a plastic material, moisture may penetrate into the substrate and then into the thin-film transistor or the light-emitting element layer, which may deteriorate the performance of the display device. The display device according to an example embodiment of the present disclosure may be composed of two substrates, that is, the first substrate and the second substrate made of a plastic material in order to prevent performance degradation of the display device due to the moisture permeation. Further, the intermediate layer made of an inorganic material may be disposed between the first substrate and the second substrate so as to prevent moisture from penetrating the substrate, thereby may improve the performance reliability of the product. The intermediate layer may be composed of an inorganic film. For example, the intermediate layer may be composed of a single layer of silicon nitride (SiNx) or silicon oxide (SiOx) or a stack of multiple layers made thereof. However, the present disclosure is not limited thereto.

The display device formed on the substrate 1000 may include a plurality of areas. In one or more example embodiments of the present disclosure, the plurality of areas include a display area AA and a non-display area NA. However, embodiments of the present disclosure are not limited thereto.

A buffer layer 1100 may be disposed on one surface of the substrate 1000 and in the display area AA and the non-display area NA. The buffer layer 1100 may improve adhesion between layers formed on the buffer layer 1100 and the substrate 1000, and may perform a role of blocking various types of defect-causing factors, such as alkali components flowing out from the substrate 1000. Further, the buffer layer 1100 may prevent or reduce diffusion of moisture or oxygen that has penetrated into the substrate 1000.

The buffer layer 1100 may be composed of a single layer made of silicon nitride (SiNx) or silicon oxide (SiOx) or a stack of multiple layers made thereof. When the buffer layer 1100 is composed of the stack of the multiple layers, the stack may include silicon oxide layers (SiOx) and silicon nitride layers (SiNx) which may be alternately stacked on top of each other.

The buffer layer 1100 may be omitted based on a type and a material of the substrate, a structure and a type of the thin-film transistor, and the like.

Transistors may be formed on the buffer layer 1100 and in the display area AA and the non-display area NA. The transistor of the display area AA may include a switching transistor SW Tr and/or a driving transistor DR Tr for driving the pixel PXL, while the transistor of the non-display area NA may include light-emission transistors EMT1 and EMT2 and/or gate driver transistors GT1 and GT2 for driving the gate driver GIP. In an example, the gate driver transistors GT1 and GT2 are located inside the gate driver GIP, but the light-emission transistors EMT1 and EMT2 are located outside the gate driver GIP. In another example, the gate driver transistors GT1 and GT2 are located inside the gate driver GIP, and the light-emission transistors EMT1 and EMT2 are also located inside the gate driver GIP. In one or more examples, the switching transistor SW Tr of FIG. 3 may represent the first switching thin-film transistor ST1 of FIG. 2 or the second switching thin-film transistor ST2 of FIG. 2. In one or more examples, the driving transistor DR Tr of FIG. 3 may represent the driving thin-film transistor DT of FIG. 2.

Each of a first semiconductor layer 100 of the gate driver transistor GT1, a second semiconductor layer 700 of the first light-emission transistor EMT1, and a third semiconductor layer 800 of the second light-emission transistor EMT2 disposed in the non-display area NA may be made of low-temperature polycrystalline silicon (LTPS).

A first gate insulating film 1110 may be disposed on the first semiconductor layer 100, the second semiconductor layer 700, and the third semiconductor layer 800. Since the first gate insulating film 1110 is disposed between the first semiconductor layer 100, the second semiconductor layer 700, and the third semiconductor layer 800 and a first gate electrode 110, a second gate electrode 710, and a third gate electrode 810, the first gate insulating film 1110 may electrically insulate the first semiconductor layer 100, the second semiconductor layer 700, and the third semiconductor layer 800 from the first gate electrode 110, the second gate electrode 710, and the third gate electrode 810 from each other, respectively.

A channel area and source/drain areas respectively connected to source/drain electrodes may be formed in the LPTS semiconductor layer via doping thereof.

The first gate insulating film 1110 may be made of an insulating inorganic material such as silicon nitride (SiNx) or silicon oxide (SiOx), or an insulating organic material. However, the present disclosure is not limited thereto.

The first gate electrode 110, the second gate electrode 710, and the third gate electrode 810 may be disposed so as to overlap the first semiconductor layer 100, the second semiconductor layer 700, and the third semiconductor layer 800, respectively.

Each of the first gate electrode 110, the second gate electrode 710 and the third gate electrode 810 may be composed of a single layer or a stack of multiple layers made of at least one of silver (Ag), molybdenum (Mo), copper (Cu), titanium (Ti), aluminum (Al), chromium (Cr), nickel (Ni), neodymium (Nd), tungsten (W) or gold (Au), or an alloy thereof. However, the present disclosure is not limited thereto.

A first interlayer insulating film 1120 and a first insulating layer 1130 may be disposed on the first gate electrode 110, the second gate electrode 710, and the third gate electrode 810.

Each of the first interlayer insulating film 1120 and the first insulating layer 1130 may be made of an insulating inorganic material such as silicon nitride (SiNx) or silicon oxide (SiOx), or may be made of an insulating organic material or another material. However, the present disclosure is not limited thereto.

A first source electrode 120S and a first drain electrode 120D connected to the first semiconductor layer 100, a second source electrode 720S and a second drain electrode 720D connected to the second semiconductor layer 700, and a third source electrode 820S and a third drain electrode 820D connected to the third semiconductor layer 800 may be disposed on the first insulating layer 1130.

The first source electrode 120S, the first drain electrode 120D, the second source electrode 720S, the second drain electrode 720D, the third source electrode 820S, and the third drain electrode 820D may be formed in the same process. Each of the first source electrode 120S, the first drain electrode 120D, the second source electrode 720S, the second drain electrode 720D, the third source electrode 820S, and the third drain electrode 820D may be made of at least one of silver (Ag), molybdenum (Mo), copper (Cu), titanium (Ti), aluminum (Al), chromium (Cr), nickel (Ni), neodymium (Nd), tungsten (W) or gold (Au), or an alloy thereof. Alternatively, each of the first source electrode 120S, the first drain electrode 120D, the second source electrode 720S, the second drain electrode 720D, the third source electrode 820S, and the third drain electrode 820D may be composed of at least two or more layers including a first layer made of titanium (Ti), and a second layer made of at least one of molybdenum (Mo), copper (Cu), aluminum (Al), silver (Ag), chromium (Cr), gold (Au), neodymium (Nd) or nickel (Ni), or an alloy thereof. However, the present disclosure is not limited thereto.

In the same process as a process of forming the first gate electrode 110, the second gate electrode 710, and the third gate electrode 810 on the first gate insulating film 1110, a first metal layer 200 and a second metal layer 300 may be respectively formed in areas where the second gate driver transistor GT2 and the switching transistor SW Tr of the display area AA are formed, respectively. Thus, the first metal layer 200 and the second metal layer 300 may be respectively used as lower gates of the second gate driver transistor GT2 and the switching transistor SW Tr of the display area AA.

The first metal layer 200 may be electrically connected to a fourth gate electrode 220 of the second gate driver transistor GT2 so as to drive the second gate driver transistor GT2. The second metal layer 300 may be electrically connected to a sixth gate electrode 320 of the switching transistor SW Tr of the display area AA so as to drive the switching transistor SW Tr.

Each of the sub-pixels of the display area AA has at least one storage capacitor Cst. The storage capacitor Cst includes a first capacitor electrode 510 and a second capacitor electrode 520.

The first capacitor electrode 510 may be disposed on the first gate insulating film 1110 and may be formed in the same process as the process of forming the first gate electrode 110, the second gate electrode 710, the third gate electrode 810, the first metal layer 200, and the second metal layer 300.

The second capacitor electrode 520 may be disposed on the first interlayer insulating film 1120 so as to overlap the first capacitor electrode 510.

The first capacitor electrode 510 and the second capacitor electrode 520 may be made of the same material.

A second insulating layer 1140 may be disposed on the first insulating layer 1130, and a third insulating layer 1150 may be further disposed on the second insulating layer 1140, if necessary.

Each of the second insulating layer 1140 and the third insulating layer 1150 may be made of an insulating material such as silicon nitride (SiNx) or silicon oxide (SiOx), or may be made of an insulating organic material or another material. However, embodiments of the present disclosure are not limited thereto.

A fourth semiconductor layer 210 of the second gate driver transistor GT2 in the driver circuit area, and a fifth semiconductor layer 410 of the driving transistor DR Tr and a sixth semiconductor layer 310 of the switching transistor SW Tr of the sub-pixel in the display area may be disposed on the third insulating layer 1150.

The fourth semiconductor layer 210 may overlap the first metal layer 200 disposed on the first gate insulating film 1110. The sixth semiconductor layer 310 may overlap the second metal layer 300 disposed on the first gate insulating film 1110.

A light-blocking layer 400 may be disposed under the fifth semiconductor layer 410 of the driving transistor DR Tr.

The light-blocking layer 400 may be formed in the same process as the process of forming the first source electrode 120S and the first drain electrode 120D in the driver circuit area and may be disposed on the first insulating layer 1130.

Each of the fourth semiconductor layer 210, the fifth semiconductor layer 410, and the sixth semiconductor layer 310 may be made of a metal oxide semiconductor. Each of the fourth semiconductor layer 210, the fifth semiconductor layer 410, and the sixth semiconductor layer 310 may be made of, for example, one of Indium-gallium-zinc-oxide (IGZO), Indium-zinc-oxide (IZO), Indium-gallium-tin-oxide (IGTO), and Indium-gallium-oxide (IGO). However, the present disclosure is not limited thereto.

The conductivity characteristics of the metal oxide semiconductor may be improved by a doping process in which impurities are implanted therein. The metal oxide semiconductor may include a channel area in which a channel along which electrons or holes move is formed, and a source area and a drain area as conductive areas respectively disposed on both opposing sides of the channel area. A source electrode and a drain electrode may be connected to the source area and the drain area, respectively. Channel areas of the fourth semiconductor layer 210, the fifth semiconductor layer 410, and the sixth semiconductor layer 310 may overlap the fourth gate electrode 220, the fifth gate electrode 420, and the sixth gate electrode 320, respectively.

A second gate insulating film 1160 may be disposed between the fourth semiconductor layer 210, the fifth semiconductor layer 410, and the sixth semiconductor layer 310 and the fourth gate electrode 220, the fifth gate electrode 420, and the sixth gate electrode 320. The second gate insulating film 1160 may be made of an insulating material such as silicon nitride (SiNx) or silicon oxide (SiOx), or may be made of an insulating inorganic or organic material. However, embodiments of the present disclosure are not limited thereto.

A second interlayer insulating film 1170 may be disposed on the fourth gate electrode 220, the fifth gate electrode 420, and the sixth gate electrode 320. The second interlayer insulating film 1170 may be made of an insulating material such as silicon nitride (SiNx) or silicon oxide (SiOx), or may be made of an insulating inorganic or organic material. However, embodiments of the present disclosure are not limited thereto.

On the second interlayer insulating film 1170, a fourth source electrode 230S and a fourth drain electrode 230D of the second gate driver transistor GT2, a fifth source electrode 430S and a fifth drain electrode 430D of the driving transistor DR Tr, and a sixth source electrode 330S and a sixth drain electrode 330D of the switching transistor SW Tr may be formed. The fourth source electrode 230S and the fourth drain electrode 230D of the second gate driver transistor GT2, the fifth source electrode 430S and the fifth drain electrode 430D of the driving transistor DR Tr, and the sixth source electrode 330S and the sixth drain electrode 330D of the switching transistor SW Tr may be respectively connected to the source area and the drain area of the fourth semiconductor layer 210, the source area and the drain area of the fifth semiconductor layer 410, and the source area and the drain area of the sixth semiconductor layer 310 via contact-holes formed in the second gate insulating film 1160 and the second interlayer insulating film 1170, respectively.

A third interlayer insulating film 1180 may be further disposed between the second interlayer insulating film 1170 and the fourth source electrode 230S and the fourth drain electrode 230D of the second gate driver transistor GT2, between the second interlayer insulating film 1170 and the fifth source electrode 430S and the fifth drain electrode 430D of the driving transistor DR Tr, and between the second interlayer insulating film 1170 and the sixth source electrode 330S and sixth drain electrode 330D of the switching transistor SW Tr.

The third interlayer insulating film 1180 may be made of an insulating material such as silicon nitride (SiNx) or silicon oxide (SiOx), or may be made of an insulating inorganic or organic material. However, embodiments of the present disclosure are not limited thereto.

The light-blocking layer 400 positioned under the fifth semiconductor layer 410 of the driving transistor DR Tr may be connected to the fifth drain electrode 430D.

The light-blocking layer 400 may prevent light from being directed to the fifth semiconductor layer 410, and may be connected to the fifth drain electrode 430D so as to prevent a phenomenon that parasitic carriers are accumulated in the fifth semiconductor layer 410, resulting in a rapid increase in drain current or to prevent a threshold voltage from changing due to this phenomenon.

The light-blocking layer 400 may be made of the same material as that of each of the first source electrode 120S and the first drain electrode 120D. That is, the light-blocking layer 400 may be composed of at least two or more layers including a first layer made of titanium (Ti), and a second layer made of at least one of molybdenum (Mo), copper (Cu), aluminum (Al), silver (Ag), chromium (Cr), gold (Au), neodymium (Nd) or nickel (Ni), or an alloy thereof. However, the present disclosure is not limited thereto.

The driving transistor DR Tr may include the fifth semiconductor layer 410 made of the metal oxide semiconductor and thus may act as a high mobility element having a mobility of 40 cm²/Vs or greater.

This driving transistor DR Tr may increase the S-factor to reduce the luminance deviation due to a gate voltage distribution.

In this regard, “S-factor” refers to a current-voltage characteristic of a thin-film transistor, and may mean a magnitude of a gate voltage required to increase a drain current by 10 times when the gate voltage below a threshold voltage is applied thereto. The S-factor may be referred to as “subthreshold slope.”

The metal oxide semiconductor may become conductive due to hydrogen. This may cause variations in the characteristics of the components of the driving transistor DR Tr.

Titanium (Ti) has a function of adsorbing hydrogen. Thus, when the light-blocking layer 400 including titanium (Ti) is disposed around the fifth semiconductor layer 410 of the driving transistor DR Tr, the light-blocking layer 400 may prevent light from penetrating the fifth semiconductor layer 410 of the driving transistor DR Tr, and further prevent hydrogen from penetrating the fifth semiconductor layer 410 of the driving transistor DR Tr.

A first planarization layer 1190 is disposed on the fourth source electrode 230S and the fourth drain electrode 230D of the second gate driver transistor GT2, the fifth source electrode 430S and the fifth drain electrode 430D of the driving transistor DR Tr, and the sixth source electrode 330S and the sixth drain electrode 330D of the switching transistor SW Tr.

The first planarization layer 1190 may be made of an organic insulating film such as polyacrylate or polyimide, and may reduce a step caused by the lines and contact-holes formed thereunder. However, embodiments of the present disclosure are not limited thereto.

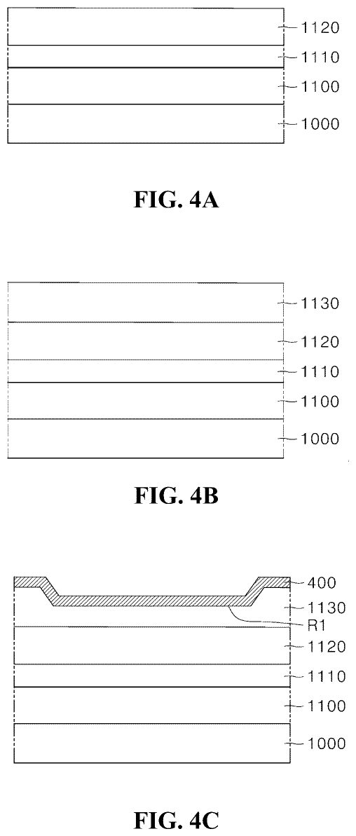

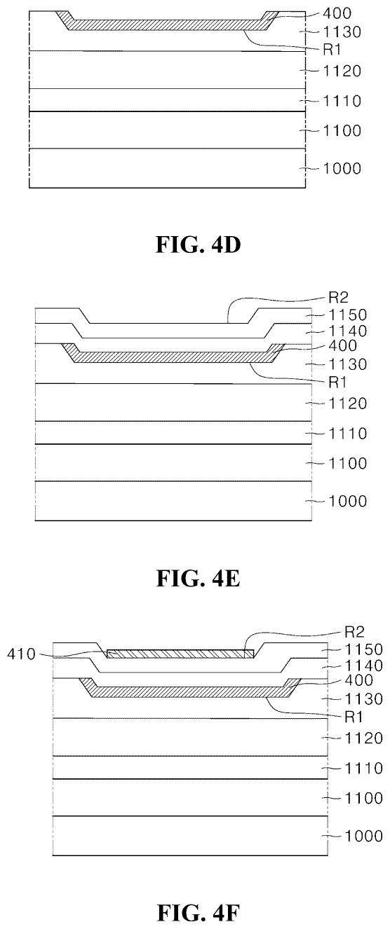

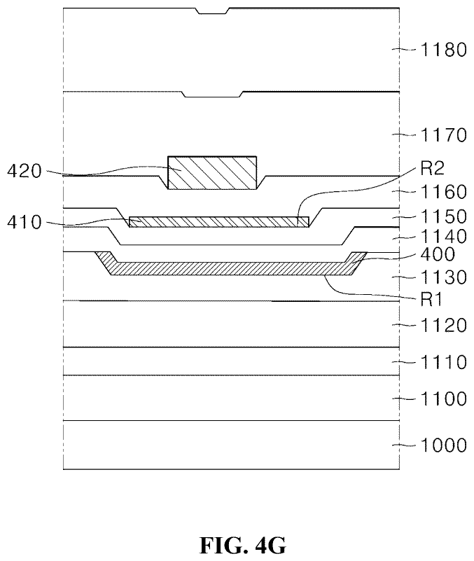

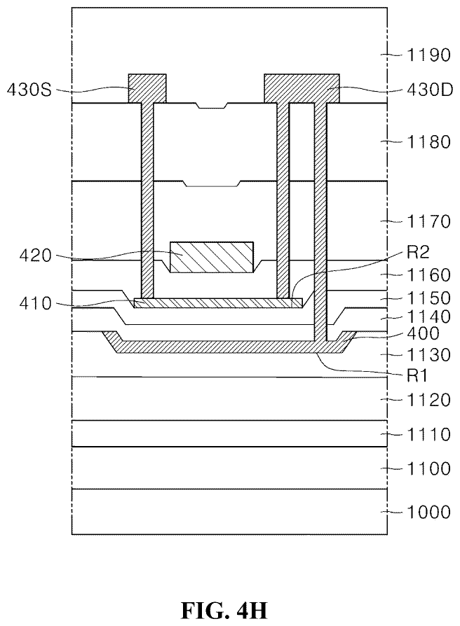

FIG. 4A and FIG. 4I are cross-sectional views illustrating a method for forming a driving transistor DR Tr according to an example embodiment of the present disclosure.

Referring to FIGS. 4A and 4B, the buffer layer 1100, the first gate insulating film 1110, the first interlayer insulating film 1120, and the first insulating layer 1130 may be formed on the substrate 1000.

Referring to FIG. 4C, after forming the first insulating layer 1130, a first recess R1 may be formed in the first insulating layer 1130 using a mask process and an etching process.

Then, a metal layer may be deposited on the first insulating layer 1130 to form the light-blocking layer 400.

As shown in FIG. 4D, the light-blocking layer 400 may be formed only in the first recess R1 of the first insulating layer 1130 via a patterning process.

The first insulating layer 1130 may have a first portion in which the first recess R1 in which the light-blocking layer 440 is disposed is formed, and a second portion where the first recess R1 is not formed. In this regard, the first portion and the second portion have different thicknesses. A thickness of the first portion is smaller than a thickness of the second portion.

A thickness of a portion of the first insulating layer 1130 overlapping the sixth semiconductor layer 310 may be larger than a thickness of a portion of the first insulating layer 1130 overlapping the fifth semiconductor layer 410.

Accordingly, the sixth semiconductor layer 310 may be disposed at a higher level than that of the fifth semiconductor layer 410 with respect to the substrate 1000. For example, a vertical distance between the sixth semiconductor layer 310 and the substrate 1000 is greater than a vertical distance between the fifth semiconductor layer 410 and the substrate 1000.

As shown in FIG. 4E, the second insulating layer 1140 and the third insulating layer 1150 may be formed on the light-blocking layer 400 and the first insulating layer 1130.

Each of the second insulating layer 1140 and the third insulating layer 1150 may be embodied as an inorganic insulating film, and may be composed of a single layer made of silicon nitride (SiNx) or silicon oxide (SiOx) or of a stack of multiple layers made thereof.

In a chemical vapor deposition process, the inorganic insulating film may be conformally formed along an underlying portion, and thus may be formed so as to have the same shape as that of the underlying portion. Thus, a second recess R2 may be formed in the third insulating layer 1150 so as to be conformally formed along and on the first recess R1, so that the first recess R1 and the second recess R2 may overlap each other vertically.

As shown in FIG. 4F, the fifth semiconductor layer 410 may be formed in the second recess R2 of the third insulating layer 1150.

The fifth semiconductor layer 410 may be disposed in the second recess R2 so that the light-blocking layer 400 formed in the first recess R1 surrounds lower and side surfaces of the fifth semiconductor layer 410.

Accordingly, the light-blocking layer 400 may prevent light from the outside entering the fifth semiconductor layer 410 and may absorb hydrogen so as to prevent the hydrogen from being diffused into the fifth semiconductor layer 410.

As shown in FIG. 4G, the second gate insulating film 1160, the fifth gate electrode 420, the second interlayer insulating film 1170, and the third interlayer insulating film 1180 are formed on the fifth semiconductor layer 410.

Each of the second gate insulating film 1160, the second interlayer insulating film 1170, and the third interlayer insulating film 1180 may be embodied as an inorganic insulating film and, more specifically, may be composed of a single layer made of silicon nitride (SiNx) or silicon oxide (SiOx) or of a stack of multiple layers made thereof.

In a chemical vapor deposition process, the inorganic insulating film may be conformally formed along an underlying portion, and thus may be formed so to have the same shape as that of the underlying portion.

As shown in FIG. 4H, the fifth drain electrode 430D connected to the light-blocking layer 400 and the fifth semiconductor layer 410, and the fifth source electrode 430S connected to the fifth semiconductor layer 410 are disposed on the third interlayer insulating film 1180.

The first planarization layer 1190 is disposed on the fifth drain electrode 430D and the fifth source electrode 430S and may be made of at least one organic insulating material selected among BenzoCycloButene (BCB), acryl resin, epoxy resin, phenolic resin, polyamide resin, and polyimide resin. However, the present disclosure is not limited thereto.

The organic insulating material may be used to planarize steps of an underlying layer.

Referring back to FIG. 3, an anode electrode 600 may be disposed on the first planarization layer 1190. The anode electrode 600 may be connected to the fifth drain electrode 430D via a contact-hole formed in the first planarization layer 1190.

A second planarization layer and a connection electrode may be further formed between the first planarization layer 1190 and the anode electrode 600. The anode electrode 600 and the fifth drain electrode 430D may be electrically connected to each other using the connection electrode.

A first connection line 630 may be formed on the gate driver transistors GT1 and GT2 or the light-emission transistors EMT1 and EMT2 of the non-display area NA and may be formed in the same process as a process of forming the anode electrode 600.

Each of the anode electrode 600 and the first connection line 630 may be made of at least one or more of silver (Ag), aluminum (Al), gold (Au), molybdenum (Mo), tungsten (W), chromium (Cr), lead (Pd), an alloy thereof, indium tin oxide (ITO), or indium zinc oxide (IZO). However, embodiments of the present disclosure are not limited thereto.

A bank 1200 may be disposed on the anode electrode 600, the first connection line 630, and the first planarization layer 1190.

The bank 1200 may distinguish a plurality of sub-pixels from each other, minimize light blurring, and prevent color mixing occurring at various viewing angles.

The bank 1200 may have an opening defined therein so as to expose a portion of the anode electrode 600 corresponding to a light-emitting area and may overlap with an end portion of the anode electrode 600.

Further, the bank 1200 may overlap a hole formed in the first planarization layer 1190 and a contact-hole formed in the second interlayer insulating film 1170 and the third interlayer insulating film 1180.

Referring to FIG. 3, the opening defined in the bank 1200 exposing the portion of the anode electrode 600 may overlap a hole formed in the first planarization layer 1190 and a hole formed in the second interlayer insulating film 1170 and the third interlayer insulating film 1180.

The bank 1200 may be made of an inorganic insulating material such as silicon nitride (SiNx) or silicon oxide (SiOx), or may be made of at least one organic insulating material among BenzoCycloButene (BCB), acryl resin, epoxy resin, phenolic resin, polyamide resin, and polyimide resin. However, the present disclosure is not limited thereto.

A spacer 1210 may be further disposed on the bank 1200. The spacer 1210 maintains a gap between the substrate 1000 on which a light-emitting element layer 610 is formed and a cover window 2000, thereby minimizing damage to an element (or a component) inside the display panel when a physical impact from the outside is applied thereto. In one or more examples, the light-emitting element layer 610 may be referred to as a light-emitting layer. The spacer 1210 may be made of the same material as that of the bank 1200, and the spacer 1210 and the bank 1200 may be formed simultaneously. However, the present disclosure is not limited thereto.

The light-emitting element layer 610 may be disposed in the opening of the bank 1200 partially exposing the anode electrode 600. The light-emitting element layer 610 may include at least one of a red light-emitting layer, a green light-emitting layer, a blue light-emitting layer, and a white light-emitting layer in order to emit light of a specific color.

When the light-emitting element layer 610 includes the white organic light-emitting layer, the light-emitting element layer 610 may be disposed in the opening of the bank 1200 and over an entire surface of the substrate.

A color filter may be disposed on the light-emitting element layer 610 so as to convert white light emitted from the white organic light-emitting layer into light of a different color from the white color. The light-emitting element layer 610 may include not only the light-emitting layer, but also a hole injection layer, a hole transport layer, an electron transport layer, and an electron injection layer. However, the present disclosure is not limited thereto.

A cathode electrode 620 may be disposed on the light-emitting element layer 610. The cathode electrode 620 supplies electrons to the light-emitting element layer 610 and may be made of a conductive material having a low work function.

When the display device 10 is of a top emission type, the cathode electrode 620 may be made of a transparent conductive material through which light transmits. For example, the transparent conductive material may include indium tin oxide (ITO), and/or indium zinc oxide (IZO). However, the present disclosure is not limited thereto.

Alternatively, the cathode electrode 620 may be made of a semi-transmissive conductive material that transmits light therethrough. For example, the cathode electrode 620 may be made of at least one or more of LiF/Al, CsF/Al, Mg:Ag, Ca/Ag, Ca:Ag, LiF/Mg:Ag, LiF/Ca/Ag, and LiF/Ca:Ag. However, the present disclosure is not limited thereto.

When the display device 10 is of a bottom emission type, the cathode electrode 620 may act as a reflective electrode that reflects light therefrom and may be made of an opaque conductive material. For example, the cathode electrode 620 may be made of at least one of silver (Ag), aluminum (Al), gold (Au), molybdenum (Mo), tungsten (W) or chromium (Cr), or an alloy thereof.

In the non-display area NA of the display device 10, a driver circuit area and a side end area including a dam area in which a plurality of dams are disposed are disposed. The side end area of the non-display area NA may be an area where the display device 10 is sealed using a connection portion where the cathode electrode 620 and the EVSS line are electrically connected to each other, an encapsulation layer, and a plurality of dams. The driver circuit area may include the gate driver transistors GT1 and GT2. The driver circuit area may further include the light-emission transistors EMT1 and EMT2. In one or more examples, the driver circuit area may be an area where the gate driver GIP is located.

The buffer layer 1100, the first gate insulating film 1110, the first interlayer insulating film 1120, and the first insulating layer 1130 disposed on the substrate 1000 may extend so as to be disposed in the side end area.

Lines may be disposed in the side end area so that the power voltage and the touch signal applied from the FPCB of the display device 10 are applied to the display panel via the lines.

A second connection line 640 may be disposed on the first insulating layer 1130.

The second connection line 640 may be formed in the same process as a process for forming the second source electrode 720S, the second drain electrode 720D, the third source electrode 820S, and the third drain electrode 820D. However, embodiments of the present disclosure are not limited thereto.

The plurality of dams may be disposed in the side end area of the non-display area NA. An example embodiment of the present disclosure illustrates that the dam area includes a plurality of dams, and the plurality of dams include a first dam DAM1 and a second dam DAM2. However, the present disclosure is not limited thereto.

In order to prevent leakage of a second encapsulation layer 1310 made of the organic material, each of the first dam DAM1 and the second dam DAM2 may have a stack structure in which at least one insulating layer may be stacked. However, embodiments of the present disclosure are not limited thereto.

The first dam DAM1 and the second dam DAM2 may have a first height and a second height, respectively, and may surround the display area AA.

The second height is larger than the first height. Thus, even when the material of the second encapsulation layer 1310 flows over the first dam DAM1, the second dam DAM2 may block the material of the second encapsulation layer 1310.

Each of the first dam DAM1 and the second dam DAM2 may be composed of a portion of the first planarization layer 1190 and a portion of the bank 1200. The second dam DAM2 may be further composed of a portion of the spacer 1210.

The second connection line 640 may extend so as to be disposed under the portion of the first planarization layer 1190 constituting the first dam DAM1.

The first connection line 630 may be disposed between the portion of the first planarization layer 1190 constituting the first dam DAM1 and the second dam DAM2 and the portion of the bank 1200 constituting the first dam DAM1 and the second dam DAM2. The first connection line 630 may be disposed on a side surface and an upper surface of the portion of the first planarization layer 1190 constituting the first dam DAM1 and the second dam DAM2.

In areas of the first dam DAM1 and the second dam DAM2 where the first planarization layer 1190 is not formed, the first connection line 630, the second connection line 640, and the cathode electrode 620 may contact each other and thus may be electrically connected to each other.

A capping layer may be disposed on the cathode electrode 620. The capping layer may be embodied as an organic or inorganic film that protects the cathode electrode 620 and improves external light efficiency. Alternatively, the capping layer may be composed of an inorganic film and may be made of a metal material such as lithium fluoride (LiF), and the capping layer may further include an organic film. However, embodiments of the present disclosure are not limited thereto.

An encapsulation may be disposed on the cathode electrode 620 and the capping layer. The encapsulation may protect the display device 10 from external moisture, oxygen, or foreign matter. For example, the encapsulation may prevent penetration of oxygen and moisture from the outside into a light-emitting material and an electrode material in order to prevent oxidation of the light-emitting material and the electrode material.

The encapsulation may be made of a transparent material so that light emitted from the light-emitting element layer 610 transmits therethrough.

The encapsulation may include a first encapsulation layer 1300, the second encapsulation layer 1310, and a third encapsulation layer 1320 so as to prevent penetration of moisture or oxygen into the light-emitting material and the electrode material. However, embodiments of the present disclosure are not limited thereto.

The first encapsulation layer 1300, the second encapsulation layer 1310, and the third encapsulation layer 1320 may be sequentially stacked. However, embodiments of the present disclosure are not limited thereto.

Each of the first encapsulation layer 1300 and the third encapsulation layer 1320 may be made of at least one inorganic material selected from among silicon nitride (SiNx), silicon oxide (SiOx), and aluminum oxide (AlyOz). However, the present disclosure is not limited thereto.

The second encapsulation layer 1310 may cover foreign substances or particles that may occur in the manufacturing process. Further, the second encapsulation layer 1310 may planarize a surface of the first encapsulation layer 1300.

The second encapsulation layer 1310 may be made of an organic material, for example, silicon oxycarbon (SiOCz), epoxy, polyimide, polyethylene, or acrylate-based polymer. However, the present disclosure is not limited thereto.

A cover window 2000 may be disposed on the third encapsulation layer 1320.

The third encapsulation layer 1320 and the cover window 2000 may be bonded to each other via an adhesive layer 1330 disposed between the third encapsulation layer 1320 and the cover window 2000. A touch electrode and a touch insulating film for a touch operation may be further formed between the third encapsulation layer 1320 and the cover window 2000.

A display device according to one or more example embodiments of the present disclosure may be described as follows.

One or more aspects of the present disclosure provide a display device that may include: a substrate; a display area; a non-display area disposed around the display area; a driver circuit area and a dam area disposed in the non-display area; a first transistor disposed in the display area, wherein the first transistor includes a first semiconductor layer, a first gate electrode, a first source electrode, and a first drain electrode; a second transistor disposed in the driver circuit area, wherein the second transistor includes a second semiconductor layer, a second gate electrode, a second source electrode, and a second drain electrode; and a first insulating film disposed between the second gate electrode and the second source electrode and between the second gate electrode and the second drain electrode; an anode electrode electrically connected to the first drain electrode; and a light-blocking layer overlapping the first semiconductor layer, wherein the light-blocking layer is disposed on the first insulating film, and wherein the light-blocking layer, the second source electrode, and the second drain electrode are disposed on a same layer.

In one or more implementations of the present disclosure, the first insulating film has a first recess defined in the first insulating film, wherein the light-blocking layer is disposed in the first recess.

In one or more implementations of the present disclosure, the display device further comprises a second insulating film disposed between the light-blocking layer and the first semiconductor layer, wherein the second insulating film has a second recess defined in the second insulating film, and wherein the second recess vertically overlaps the first recess.

In one or more implementations of the present disclosure, the first semiconductor layer is disposed in the second recess.

In one or more implementations of the present disclosure, the first drain electrode is connected to the first semiconductor layer and the light-blocking layer.

In one or more implementations of the present disclosure, the display device further comprises a third transistor disposed in the display area, wherein the third transistor includes a third semiconductor layer, a third gate electrode, a third source electrode, and a third drain electrode.

In one or more implementations of the present disclosure, the third semiconductor layer is disposed on the first insulating film.

In one or more implementations of the present disclosure, a thickness of a portion of the first insulating film overlapping the third semiconductor layer is larger than a thickness of a portion of the first insulating film overlapping the first semiconductor layer.

In one or more implementations of the present disclosure, the third semiconductor layer is disposed at a higher vertical level than a vertical level of the first semiconductor layer, with respect to the substrate.

In one or more implementations of the present disclosure, each of the first semiconductor layer and the third semiconductor layer is made of an oxide semiconductor, and the second semiconductor layer is made of a polycrystalline silicon semiconductor.

In one or more implementations of the present disclosure, the display device further comprises a storage capacitor disposed in the display area, wherein the storage capacitor is composed of a first capacitor electrode and a second capacitor electrode.

In one or more implementations of the present disclosure, a first interlayer insulating film is disposed between the second gate electrode and the first insulating film, wherein the first capacitor electrode is disposed on the first interlayer insulating film.

In one or more implementations of the present disclosure, the second capacitor electrode and the second gate electrode are made of a same material and are disposed on a same layer.

In one or more implementations of the present disclosure, the display device further comprises a light-emitting layer disposed on the anode electrode, and a cathode electrode disposed on the light-emitting layer.

In one or more implementations of the present disclosure, the display device further comprises a first connection line disposed on the second transistor, wherein the first connection line is electrically connected to the cathode electrode in the dam area.

One or more aspects of the present disclosure provide a display device that may include: a substrate; a display area; a non-display area disposed around the display area; a first insulating film disposed on the substrate; a first transistor disposed in the display area and on the first insulating film, wherein the first transistor includes a first semiconductor layer, a first gate electrode, a first source electrode, and a first drain electrode; an anode electrode electrically connected to the first drain electrode; a light-emitting layer disposed on the anode electrode; a cathode electrode disposed on the light-emitting layer; and a light-blocking layer disposed on the first insulating film, wherein the first insulating film has a first recess defined in the first insulating film, and wherein the light-blocking layer is disposed in the first recess.

In one or more implementations of the present disclosure, the display device further comprises a second insulating film disposed between the light-blocking layer and the first semiconductor layer, wherein the second insulating film has a second recess defined in the second insulating film, and wherein the second recess vertically overlaps the first recess.

In one or more implementations of the present disclosure, the first semiconductor layer is disposed in the second recess.

In one or more implementations of the present disclosure, the first drain electrode is connected to the first semiconductor layer and the light-blocking layer.

In one or more implementations of the present disclosure, the display device further comprises a second transistor disposed in the display area, wherein the second transistor includes a second semiconductor layer, a second gate electrode, a second source electrode and a second drain electrode.

In one or more implementations of the present disclosure, the second semiconductor layer is disposed on the second insulating film.

In one or more implementations of the present disclosure, a thickness of a portion of the first insulating film overlapping the second semiconductor layer is larger than a thickness of a portion of the first insulating film overlapping the first semiconductor layer.

In one or more implementations of the present disclosure, the second semiconductor layer is disposed at a higher vertical level than a vertical level of the first semiconductor layer, with respect to the substrate.

In one or more implementations of the present disclosure, the display device further comprises a driver circuit area and a dam area disposed in the non-display area, wherein the display device further comprises a third transistor disposed in the driver circuit area, and wherein the third transistor includes a third semiconductor layer, a third gate electrode, a third source electrode, and a third drain electrode.

In one or more implementations of the present disclosure, each of the first semiconductor layer and the second semiconductor layer is made of an oxide semiconductor, and the third semiconductor layer is made of a polycrystalline silicon semiconductor.

In one or more implementations of the present disclosure, the display device further comprises a storage capacitor disposed in the display area, wherein the storage capacitor is composed of a first capacitor electrode and a second capacitor electrode.

In one or more implementations of the present disclosure, a first interlayer insulating film is disposed between the third gate electrode and the first insulating film, wherein the first capacitor electrode is disposed on the first interlayer insulating film.

In one or more implementations of the present disclosure, the second capacitor electrode and the third gate electrode are disposed on a same layer.

In one or more implementations of the present disclosure, the display device further comprises a first connection line disposed on the third transistor, wherein the first connection line is electrically connected to the cathode electrode in the dam area.

Although the embodiments of the present disclosure have been described in more detail with reference to the accompanying drawings, the present disclosure is not necessarily limited to these embodiments, and may be modified in a various manner within the technical idea or the scope of the present disclosure. Accordingly, the embodiments as disclosed in the present disclosure are intended to describe example embodiments rather than limit the technical idea of the present disclosure, and the scope of the present disclosure is not limited by these embodiments. Therefore, it should be understood that the embodiments described above are not restrictive but illustrative in all respects. Further, it will be apparent to those skilled in the art that various modifications and variations can be made in the present disclosure without departing from the technical idea or scope of the present disclosure. Thus, it is intended that the present disclosure covers the modifications and variations of this disclosure that come within the scope of the claims and their equivalents.

What is claimed is:

1. A display device, comprising:
a substrate;
a display area;
a non-display area disposed around the display area;
a driver circuit area and a dam area disposed in the non-display area;
a first transistor disposed in the display area, wherein the first transistor includes a first semiconductor layer, a first gate electrode, a first source electrode, and a first drain electrode;
a second transistor disposed in the driver circuit area, wherein the second transistor includes a second semiconductor layer, a second gate electrode, a second source electrode, and a second drain electrode; and
a first insulating film disposed between the second gate electrode and the second source electrode and between the second gate electrode and the second drain electrode;
an anode electrode electrically connected to the first drain electrode; and
a light-blocking layer overlapping the first semiconductor layer,
wherein the light-blocking layer is disposed on the first insulating film, and
wherein the light-blocking layer, the second source electrode, and the second drain electrode are disposed on a same layer.

2. The display device of claim 1, wherein the first insulating film has a first recess defined in the first insulating film, and wherein the light-blocking layer is disposed in the first recess.

3. The display device of claim 2, wherein the display device further comprises a second insulating film disposed between the light-blocking layer and the first semiconductor layer,
wherein the second insulating film has a second recess defined in the second insulating film, and
wherein the second recess vertically overlaps the first recess.

4. The display device of claim 3, wherein the first semiconductor layer is disposed in the second recess.

5. The display device of claim 1, wherein the first drain electrode is connected to the first semiconductor layer and the light-blocking layer.

6. The display device of claim 3, wherein the display device further comprises a third transistor disposed in the display area, and
wherein the third transistor includes a third semiconductor layer, a third gate electrode, a third source electrode, and a third drain electrode.

7. The display device of claim 6, wherein the third semiconductor layer is disposed on the first insulating film.

8. The display device of claim 6, wherein a thickness of a portion of the first insulating film overlapping the third semiconductor layer is larger than a thickness of a portion of the first insulating film overlapping the first semiconductor layer.

9. The display device of claim 6, wherein the third semiconductor layer is disposed at a higher vertical level than a vertical level of the first semiconductor layer, with respect to the substrate.

10. The display device of claim 6, wherein each of the first semiconductor layer and the third semiconductor layer is made of an oxide semiconductor, and the second semiconductor layer is made of a polycrystalline silicon semiconductor.

11. The display device of claim 1, wherein the display device further comprises a storage capacitor disposed in the display area, and
wherein the storage capacitor is composed of a first capacitor electrode and a second capacitor electrode.

12. The display device of claim 11, wherein a first interlayer insulating film is disposed between the second gate electrode and the first insulating film, and
wherein the first capacitor electrode is disposed on the first interlayer insulating film.

13. The display device of claim 12, wherein the second capacitor electrode and the second gate electrode are made of a same material and are disposed on a same layer.

14. The display device of claim 1, wherein the display device further comprises a light-emitting layer disposed on the anode electrode, and a cathode electrode disposed on the light-emitting layer.

15. The display device of claim 14, wherein the display device further comprises a first connection line disposed on the second transistor, and wherein the first connection line is electrically connected to the cathode electrode in the dam area.

16. A display device, comprising:
a substrate;
a display area;
a non-display area disposed around the display area;
a first insulating film disposed on the substrate;
a first transistor disposed in the display area and on the first insulating film, wherein the first transistor includes a first semiconductor layer, a first gate electrode, a first source electrode, and a first drain electrode;
an anode electrode electrically connected to the first drain electrode;
a light-emitting layer disposed on the anode electrode;
a cathode electrode disposed on the light-emitting layer; and
a light-blocking layer disposed on the first insulating film,
wherein the first insulating film has a first recess defined in the first insulating film, and
wherein the light-blocking layer is disposed in the first recess.

17. The display device of claim 16, wherein the display device further comprises a second insulating film disposed between the light-blocking layer and the first semiconductor layer,
wherein the second insulating film has a second recess defined in the second insulating film, and
wherein the second recess vertically overlaps the first recess.

18. The display device of claim 17, wherein the first semiconductor layer is disposed in the second recess.

19. The display device of claim 16, wherein the first drain electrode is connected to the first semiconductor layer and the light-blocking layer.

20. The display device of claim 17, wherein the display device further comprises a second transistor disposed in the display area, and
wherein the second transistor includes a second semiconductor layer, a second gate electrode, a second source electrode and a second drain electrode.

21. The display device of claim 20, wherein the second semiconductor layer is disposed on the second insulating film.

22. The display device of claim 20, wherein a thickness of a portion of the first insulating film overlapping the second semiconductor layer is larger than a thickness of a portion of the first insulating film overlapping the first semiconductor layer.

23. The display device of claim 20, wherein the second semiconductor layer is disposed at a higher vertical level than a vertical level of the first semiconductor layer, with respect to the substrate.

24. The display device of claim 20, wherein the display device further comprises a driver circuit area and a dam area disposed in the non-display area,
wherein the display device further comprises a third transistor disposed in the driver circuit area, and
wherein the third transistor includes a third semiconductor layer, a third gate electrode, a third source electrode, and a third drain electrode.

25. The display device of claim 24, wherein each of the first semiconductor layer and the second semiconductor layer is made of an oxide semiconductor, and the third semiconductor layer is made of a polycrystalline silicon semiconductor.

26. The display device of claim 24, wherein the display device further comprises a storage capacitor disposed in the display area, and
wherein the storage capacitor is composed of a first capacitor electrode and a second capacitor electrode.

27. The display device of claim 26, wherein a first interlayer insulating film is disposed between the third gate electrode and the first insulating film, and
wherein the first capacitor electrode is disposed on the first interlayer insulating film.

28. The display device of claim 26, wherein the second capacitor electrode and the third gate electrode are disposed on a same layer.

29. The display device of claim 24, wherein the display device further comprises a first connection line disposed on the third transistor, and
wherein the first connection line is electrically connected to the cathode electrode in the dam area.
